(19) United States
(12) Patent Application Publication
(10) Pub. No.: US 2017/0167041 A1
(43) Pub. Date: Jun. 15, 2017

(54) METALLIC FOAM BODY WITH CONTROLLED GRAIN SIZE ON ITS SURFACE, PROCESS FOR ITS PRODUCTION AND USE THEREOF

(71) Applicant: ALANTUM EUROPE GMBH, Oberhachig (DE)

(72) Inventors: Rene Poss, Sauerlach (DE); Shadi Saberi, Oakville (CA); Frank Deisel, Oberhaching (DE)

(21) Appl. No.: 15/038,958

(22) PCT Filed: Dec. 10, 2014
(86) PCT No.: PCT/EP2014/077276

§ 371 Date: May 24, 2016

(30) Foreign Application Priority Data
Dec. 10, 2013 (EP) 13196540.2

(51) Int. Cl. C25D 7/00; C25D 5/34; C23C 14/00; C23C 14/04; B32B 15/01; C23C 14/34; C23C 14/58; B32B 15/04; B32B 15/20; C25D 3/46; C23C 14/20

(52) U.S. Cl. CPC C25D 7/00; C25D 3/46; C25D 5/34; C23C 14/0005; C23C 14/046; C23C 14/205; C23C 14/34; C23C 14/5873; C23C 14/5846; B32B 15/043; B32B 15/046; B32B 15/20; B32B 15/018

(57) ABSTRACT

The invention relates to a metallic foam body, comprising (a) a metallic foam body substrate made of at least one metal or metal alloy A; and (b) a layer of a metal or metal alloy B present on at least a part of the surface of the metallic foam body substrate (a), wherein A and B differ in their chemical composition and/or in the grain size of the metal or metal alloy, and wherein the metal or metal alloy A and B is selected from a group consisting of Ni, Cr, Co, Cu, Ag, and any alloy thereof; obtainable by a process comprising the steps (i) provision of a porous organic polymer foam; (ii) deposition of at least one metal or metal alloy A on the porous organic polymer foam; (iii) burning off of the porous organic polymer foam to obtain the metallic foam body substrate (a); and (iv) deposition by electroplating of the metallic layer (b) of a metal or metal alloy B at least on a part of the surface of the metallic foam body (a). The invention moreover relates to a process for the production of the metallic foam body and a use of the metallic foam body.

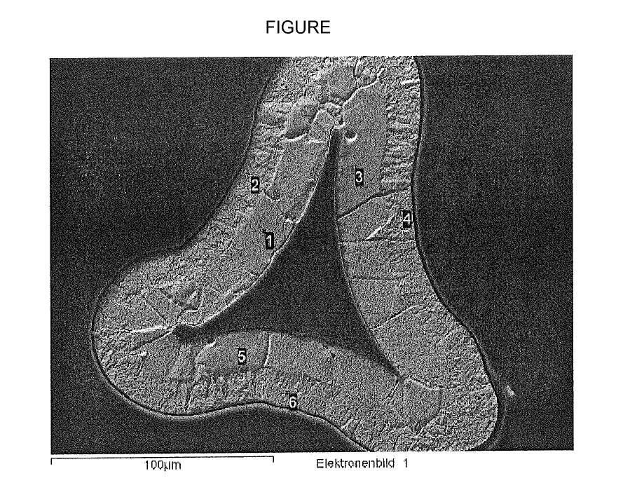

The present invention relates to a metallic foam body with controlled grain size on its surface, a process for its production and the use thereof. In particular the present invention relates to a metallic foam body, comprising (a) a metallic foam body substrate made of at least one metal or metal alloy A; and (b) a layer of a metal or metal alloy B present on at least a part of the surface of the metallic foam body substrate (a), wherein A and B differ in their chemical composition and/or in the grain size of the metal or metal alloy; a process for its production and a use thereof.

Metallic foams as precursor for catalysts or as catalysts are known. In fact, the potential advantages of metal foams as catalyst supports or catalysts have been the subject of significant attention in the chemical industry. Some of the characteristics of these foams are: large interfacial area that promotes mass and heat transfer, high thermal conductivity and mechanical strength.

In order to provide these favorable characteristics, the metallic foams have often to be produced by using a porous organic polymer as a template onto which one or more desired metals or metal alloys are deposited. The organic polymer is then burnt off at elevated temperatures to give rise to a metallic foam that can be used for a variety of applications including various adsorption and absorption processes; or as a catalytic material per se or a precursor thereof. However, in order to burn off the polymer, high temperatures need to be applied. For example, in the case of polyurethane as a template, the polyurethane template is burnt off at a temperature of up to 850° C. Under such temperature conditions many metallic surfaces change and often give rise to an increase in the grain size of metallic particles. As a result, desired surface characteristics of the metal may suffer.

It is moreover known that the grain size of catalytically active species is of great importance for many catalyzed processes. Hence there is in general a need for the provision of catalytically active materials with a defined grain size of the catalytically active species. The grain size often increases during a catalyzed reaction, especially when this reaction is carried out at high temperatures. For example, the article “Herstellung von Formaldehyd aus Methanol in der BASF” describes the synthesis of formaldehyde by oxidative dehydration of methanol using a silver crystal catalyst at 600 to 700° C. It was found in this process that the yield decreases when the temperature of the silver catalyst increases in that the amount of non-converted methanol decreases and the formation of the side products carbon monoxide and dioxide increases. This was attributed to the fact that the grain size of the silver increases at the high temperature of 700° C. at which this so-called formaldehyde process is performed, leading to a decrease of the catalytic activity of the silver catalyst.

It is thus an object of the present invention to provide a metallic foam body with a controlled grain size of the metallic particles on the foam body surface, i.e. with a grain size that is less dependent on the synthesis conditions of the metallic foam body. An object of the invention is also the provision of a process for the production of such a metallic foam body.

This object is achieved by the metallic foam body, the process for the production of the metallic foam body and the use of the metallic foam body in accordance with the respective independent claims. Preferred embodiments of the metallic foam body, the process for its production as well as the use thereof are indicated in the respective dependent claims.

Preferred embodiments of the metallic foam body, the process and the use correspond to preferred embodiments of the other invention categories, even when this is not explicitly indicated.

Accordingly, the invention is directed to a metallic foam body, comprising
(a) a metallic foam body substrate made of at least one metal or metal alloy A; and
(b) a layer of a metal or metal alloy B present on at least a part of the surface of the metallic foam body substrate (a), wherein A and B differ in their chemical composition and/or in the grain size of the metal or metal alloy, and wherein the metal or metal alloy A and B is selected from a group consisting of Ni, Cr, Co, Cu, Ag, and any alloy thereof;
   obtainable by a process comprising the steps
(i) provision of a porous organic polymer foam;
(ii) deposition of at least one metal or metal alloy A on the porous organic polymer foam;
(iii) burning off of the porous organic polymer foam to obtain the metallic foam body substrate (a); and
(iv) deposition by electroplating of the metallic layer (b) of a metal or metal alloy B at least on a part of the surface of the metallic foam body (a).

The deposition of at least one metal or metal alloy A on the porous organic polymer foam in step (ii) can be effected in various ways, for example by electroplating, CVD, Metal-Organic CVD (MOCVD), by a slurry method or another method. If electroplating is to be effected, the porous polymer has to be rendered in advance electrically conductive so that it becomes suitable for the electroplating process.

Preferably, step (ii) thus comprises the steps
(ii1) deposition of a first metallic layer containing a metal or metal alloy A1 by a chemical or physical vapor deposition method; and
(ii2) deposition of a second metallic layer containing a metal or metal alloy A2 by electroplating;
   wherein the metal or metal alloy A1 and A2 is selected from a group consisting of Ni, Cr, Co, Cu, Ag, and any alloy thereof, and wherein A1 and A2 are identical or different. In the context of the present invention, the meaning of A comprises A1 and A2.

In step (ii1) various chemical or physical vapor deposition methods can be used. Preferably, a sputtering method is used.

The first metallic layer serves in general to the purpose of rendering the surface of the porous organic polymer electrically conductive. Accordingly, the first metallic layer can be rather thin as long as it provides a sufficiently high electrical conductivity. It is in general sufficient that this first metallic layer has a thickness in the order of a few atoms. Preferably, the average thickness of the first metallic layer is up to 0.1 μm and the average thickness of the second metallic layer is from 5 to 50 μm. The thickness of the first metallic layer can be determined by electron microscopy.

In the production of the metallic foam body of the present invention, numerous porous organic polymers can be used. Preferably, organic polymers with open pores are used. In general, the porous organic polymer foam is selected from the group consisting of polyurethane (PU) foam, poly ethylene foam and polypropylene foam. Most preferably, a porous polyurethane (PU) foam is used. The use of a porous polyurethane (PU) foam gives rise to a particular advantageous open-celled metallic foam body.

In a particular preferred embodiment of the metallic foam body, the thickness of struts in the metallic foam body substrate (a) is in the range of from 5 to 100 μm, more preferably in the range of from 20 to 50 μm.

Preferably, the average thickness of the layer (b) of the metal or metal alloy B is from 5 to 200 μm. The thickness of the layer (b) can be determined for example by electron microscopy.

The ratio of the thickness of the metallic foam body substrate (a) made of at least one metal or metal alloy A and the thickness of the layer of a metal or metal alloy B is preferably in the range of from 0.4 to 3, more preferably in the range of from 0.5 to 2.5 and even more preferably in the range of from 0.8 to 1.5.

In the metallic foam body of the present invention, the metal or metal alloy A, A1, A2 and/or B is selected from a group consisting of Ni, Cr, Co, Cu, Ag, and any alloy thereof. In a particularly preferred embodiment, A2 and B are silver. In this embodiment, A1 may be also silver or a different metal or metal alloy. The selection of metal or metal alloy will depend to some extent on the intended application of the metallic foam body. For some catalytic purposes, the presence of a different metal might poison the silver.

In a particularly preferred embodiment of the metallic foam body, the contents of silver is at least 99.999 atom % and the contents of the elements Al, Bi, Cu, Fe, Pb, and Zn is at most 0.001 atom %, based on the total amount of metallic elements.

The metallic foam body contains only very minor amounts of carbon, nitrogen and oxygen, in general in a bonded state. Preferably, the total amount of carbon, nitrogen and oxygen is less than 0.1% by weight of the metallic foam body, more preferably less than 0.08% by weight and even more preferably less than 0.05% by weight.

As regards the present invention, the grain size is determined by electron microscopy. In the metallic foam body of the present invention, the grain size in the metallic foam body substrate (a) of a metal or metal alloy A is preferably in the range of from 1 μm to 100 μm. Moreover, the grain size in the layer (b) of a metal or metal alloy B is preferably in the range of from 1 nm to 50 μm.

The metallic foam body of the present invention has preferably a pore size of from 100 and 5000 μm, preferably in the range of from 200 to 1000 μm, a strut thickness in the range of from 5 to 100 μm, preferably in the range of from 20 to 50 μm, an apparent density in the range of from 300 to 1200 kg/m³, a specific geometrical surface area in the range of from 100 to 20000 m²/m³ and a porosity in the range of from 0.50 to 0.95.

The pore size is determined in general by a Visiocell analysis method from Recticel that is described in “The Guide 2000 of Technical Foams”, Book 4, Part 4, pages 33-41. In particular, the pore size is determined with an optical measurement of cell diameter by superimposing calibrated rings, printed on transparent paper, on the selected cell. The pore size measurement is performed at least for hundred different cells in order to obtain an average cell diameter value.

The apparent density is determined as weight per volume unit according to ISO 845.

The geometrical surface area (GSA) of the metallic foam body is determined by using 2-D foam scans and numerical methods. In particular, the GSA was determined by using an imaging technique in the following way: A foam sample (20×20 mm) with hardener (mixture of resin and epoxy hardener in 10:3 weight ratio) is placed in a holder. The sample is hardened for 30 min at 70° C. oven temperature. The foam sample is polished by using a polishing disk and water. Image capture and processing is done with “Inner View” software. Images are captured from 36 districts (one district is 1.7×2.3 mm) and analysis of the captured images is done with the software. Three maximum and three minimum are removed and GSA evaluation is done based on 30 districts according to the equation

(Aₛ/V)=Σₗ(Pₛ/Aₜₒₜₐₗ)ₗ/l
Cross-sectional area (Aₜₒₜₐₗ)
Strut area per cross-sectional area (As)
Perimeter with strut per cross-sectional area (Ps)

The porosity (in %) is calculated by the following equation:

Porosity (%)=100/VT×(VT−W(1000/ρ),

wherein VT is the foam sheet sample volume, unit [mm³]; W is the foam sheet sample weight, unit [g] and ρ is the density of the foam material.

The strut thickness is measured by electron microscopy. In particular, the strut thickness is measured by electron microscopy as an average value by using X-ray micro-tomography according to Salvo et al. (cf. Salvo, L., Cloetens, P., Maire, E., Zabler, S., Blandin, J. J., Buffière, W Y., Ludwig, W., Boller, E., Bellet, D. and Josserond, C. 2003, “X-ray micro-tomography as an attractive characterization technique in materials science”, Nuclear Instruments and Methods in Physics Research B 200 273-286), which provides 3D visualization of foam microstructure. For each strut, an equivalent hydraulic diameter (diameter equal to a cylinder of the same cross section) is calculated and statistically averaged over a large number of struts. The strut thickness is then obtained from the hydraulic diameters according to the aforementioned method of Salvo et al. as follows, whereby Ni foam is used as an illustrative example:

Foam area density(AD)[kgNi/m² foam]/Foam thickness(FT)[m]=X(kgNi/m³ of foam)

X[kgNi/m³ of foam]/Nickel density[kgNi/m³ of solid Ni]=Y[dimensionless]

Geometric Surface Area (GSA)=m²/m³

→Thickness of foam strut[m]=Y/GSA

The layer of the metal or metal alloy B may be present on a part or the entire surface of the metallic foam body substrate (a). It is however preferred that the metal or metal alloy B is present on the entire surface of the metallic foam body substrate (a). It is moreover preferable that the layer (b) on the metallic foam body substrate (a) has a uniform thickness.

The invention relates moreover to a process for the production of a metallic foam body, wherein the metallic foam body comprises
(a) a metallic foam body substrate made of at least one metal or metal alloy A; and
(b) a layer of a metal or metal alloy B present on at least a part of the surface of the metallic foam body substrate (a), wherein A and B differ in their chemical composition and/or in the grain size of the metal or metal alloy, and wherein the metal or metal alloy A and B is selected from a group consisting of Ni, Cr, Co, Cu, Ag, and any alloy thereof;
   comprising the steps
(i) provision of a porous organic polymer foam;
(ii) deposition of at least one first metal or metal alloy A on the porous organic polymer foam;
(iii) burning off of the porous organic polymer foam to obtain the metallic foam body substrate (a); and
(iv) deposition by electroplating of the metallic layer (b) of a metal or metal alloy B at least on a part of the surface of the metallic foam body substrate (a).

In the process of the present invention step (iii) is usually carried out at a temperature in the range of from 300 to 900° C.

It was found that step (iii) gives rise to a particularly advantageous metallic foam body when it is carried out in two heating steps which differ in their respective conditions. A first heating step is preferably performed at a temperature in the range of from 520 to 580° C., preferably in the range of from 540 to 560° C., for a period of from 1.5 to 5 hours, preferably for a period of from 2.5 to 4 hours, under an inert gas atmosphere, preferably under nitrogen. A second heating step is preferably performed at a temperature in the range of from 800 to 880° C., preferably in the range of from 840 to 850 or 860° C., for a period of from 5 to 100 seconds, preferably for a period of from 10 to 30 seconds, under air.

A preferred process comprises the steps
(i1) provision of a porous polyurethane foam;
(ii3) deposition of Ag in a thickness of 5 to 50 μm onto the polyurethane foam; and
(iii1) burning off the polyurethane foam at a temperature in the range of from 300 to 850° C. to obtain the metallic foam body substrate (a); and
(iv1) deposition of Ag in a thickness of 1 to 200 μm, more preferably 5 to 50 μm, by electroplating onto the metallic foam body substrate (a) obtained in step (iii1).

An even more preferred process comprises the steps
(i1) provision of a porous polyurethane foam;
(ii4) deposition of Ni or Ag by sputtering to render the polyurethane foam electrically conductive;
(ii5) deposition of Ag in a thickness of 5 to 50 μm by electroplating onto the electrically conductive polyurethane foam obtained in step (ii3); and
(iii1) burning off the polyurethane foam at a temperature in the range of from 300 to 850° C.; and
(iv1) deposition of Ag in a thickness of 1 to 200 μm, more preferably 5 to 50 μm, by electroplating onto the metallic foam body substrate (a) obtained in step (iii1).

In a further aspect, the present invention relates to the use of the metallic foam body described herein in a physical adsorption or absorption process or in a chemical process.

Examples are the removal and recovery of metals from the liquid waste streams in pharmaceutical, refining and industrial applications.

The metallic foam body of the present invention can also be used as a component in catalyst formulations for numerous catalyzed chemical reactions which involve in particular organic compounds, for example hydrogenation, isomerization, hydration, hydrogenolysis, reductive amination, reductive alkylation, dehydration, oxidation, dehydrogenation, rearrangement and other reactions.

In a preferred use, the metallic foam body is used as a precursor for a catalyst or as a catalyst in a process for the production of formaldehyde by oxidation of methanol. For this use, it is preferred that the metallic foam body contains more than 99 atom % silver, based on the metal components. It is even more preferred that the metallic foam body contains at least 99.999 atom % silver and not more than 0.001 atom % of the elements Al, Bi, Cu, Fe, Pb, and Zn.

It has been found that the lifetime of a catalyst in a process for the production of formaldehyde by oxidation of methanol is significantly higher when such a metallic foam body based on silver is used as compared to a silver granule catalyst. Moreover, it has been found that the required amount of silver can be significantly lower when a metallic foam body is used instead of silver granules for this process.

The metallic foam bodies of the present invention show a high porosity, are light weight and have a large surface area. Moreover, they reveal a good structural homogeneity. As regards flow, mass and heat transfer characteristics, the surface modified metal foams allow a low pressure drop, an enhanced flow mixing, high heat transfer and mass transfer rates, high thermal conductivity and a low diffusion resistance.

The invention has several advantages. The invention allows producing a catalyst or components for a catalyst to be used in a chemical process with a high mechanical stability and a very defined surface structure in that the grain size of the metallic particles on the foam body surface can be controlled. I.e. the grain size is less dependent on the synthesis conditions of the metallic foam body than with known foam bodies.

Moreover, the metallic foam body of the present invention enables good material transfer through it while the transferred material can come into contact with catalytic sites. Moreover, the use of the foam body of the present invention allows avoiding channeling.

The following examples serve to illustrate the invention and may not be construed to limit the present invention. Grain sizes as well as layer thicknesses were determined by scanning electron microscopy.

### EXAMPLE

A metallic foam body was produced by providing firstly a porous polyurethane foam with an average pore size of 450 μm as a 1.6 mm sheet. The polyurethane foam was subjected to sputtering with Ni (alternatively with Ag) to make the polyurethane foam electrically conductive. Then silver was electroplated in an average thickness of 20 μm. Thereafter, the polyurethane foam was burned off in air at a temperature of 700° C. After the burning off of the polyurethane foam the grain size had increased in comparison to the grain size directly after the deposition of the silver layer. Thereafter, a second silver layer with an average thickness of 20 μm was plated. The grain size of the final metallic foam body was similar to the grain size directly after deposition of the silver layer before the polyurethane foam was burned off. The Figure shows a cross section to the obtained silver foam, more particular a cross section of a double electroplated Ag foam strut. In the Figure, 1, 3 and 5 refer to the grain sizes in a first electroplated layer and 2, 4, 6 refer to the grain sizes in a second electroplated Ag layer. It can be clearly seen that the grain size is larger in the first electroplated layer compared to the second electroplated layer.

### Comparison Example

The Example was repeated except that a silver layer with an average thickness of 40 μm was electroplated after the polyurethane had been rendered electrically conductive. The grain size of the final metallic foam body was larger than the grain size of the final metallic foam body of the Example.

1-15. (canceled)

16. A metallic foam body, comprising
(a) a metallic foam body substrate made of at least one metal or metal alloy A; and
(b) a layer of a metal or metal alloy B present on at least a part of the surface of the metallic foam body substrate (a), wherein A and B differ in their chemical composition and/or in the grain size of the metal or metal alloy, and wherein the metal or metal alloy A and B is selected from a group consisting of Ni, Cr, Co, Cu, Ag, and any alloy thereof;
obtainable by a process comprising the steps
(i) provision of a porous organic polymer foam;
(ii) deposition of at least one metal or metal alloy A on the porous organic polymer foam;
(iii) burning off of the porous organic polymer foam to obtain the metallic foam body substrate (a); and
(iv) deposition by electroplating of the metallic layer (b) of a metal or metal alloy B at least on a part of the surface of the metallic foam body (a).

17. A metallic foam body according to claim 16, wherein step (ii) comprises the steps
(ii1) deposition of a first metallic layer containing a metal or metal alloy A1 by a chemical or physical vapor deposition method; and
(ii2) deposition of a second metallic layer containing a metal or metal alloy A2 by electroplating;
wherein the metal or metal alloy A1 and A2 is selected from a group consisting of Ni, Cr, Co, Cu, Ag, and any alloy thereof, and wherein A1 and A2 are identical or different.

18. A metallic foam body according to claim 17, wherein the average thickness of the first metallic layer is up to 0.1 μm and the average thickness of the second metallic layer is from 5 to 50 μm.

19. A metallic foam body according to claim 16, wherein the porous organic polymer foam is selected from the group consisting of polyurethane (PU) foam, poly ethylene foam and polypropylene foam.

20. A metallic foam body according to claim 16, wherein the thickness of struts in the metallic foam body substrate (a) is in the range of from 5 to 100 μm.

21. A metallic foam body according to claim 16, wherein the average thickness of the layer (b) of the metal or metal alloy B is from 5 to 200 μm.

22. A metallic foam body according to claim 16, wherein A2 and B are silver.

23. A metallic foam body according to claim 22, wherein the contents of silver is at least 99.999 atom % and the contents of the elements Al, Bi, Cu, Fe, Pb, and Zn is not more than 0.001 atom %.

24. A metallic foam body according to claim 16 having a pore size of from 100 and 5000 μm, a strut thickness in the range of from 5 to 100 μm, an apparent density in the range of from 300 to 1200 kg/m³, a specific geometric surface area in the range of from 100 to 20000 m²/m³ and a porosity in the range of from 0.50 to 0.95.

25. A metallic foam body according to claim 16, wherein the layer (b) of the metal or metal alloy B is present on the entire surface of the metallic foam body substrate (a).

26. A process for the production of a metallic foam body, wherein the metallic foam body comprises
(a) a metallic foam body substrate made of at least one metal or metal alloy A; and
(b) a layer of a metal or metal alloy B present on at least a part of the surface of the metallic foam body substrate (a), wherein A and B differ in their chemical composition and/or in the grain size of the metal or metal alloy, and wherein the metal or metal alloy A and B is selected from a group consisting of Ni, Cr, Co, Cu, Ag, and any alloy thereof;
comprising the steps
(i) provision of a porous organic polymer foam;
(ii) deposition of at least one first metal or metal alloy A on the porous organic polymer foam;
(iii) burning off of the porous organic polymer foam to obtain the metallic foam body substrate (a); and
(iv) deposition by electroplating of the metallic layer (b) of a metal or metal alloy B at least on a part of the surface of the metallic foam body substrate (a).

27. A process according to claim 26, comprising the steps
(i1) provision of a porous polyurethane foam;
(ii3) deposition of Ag in a thickness of 5 to 50 μm onto the polyurethane foam; and
(iii1) burning off the polyurethane foam at a temperature in the range of from 300 to 850° C. to obtain the metallic foam body substrate (a); and
(iv1) deposition of Ag in a thickness of 1 to 200 μm by electroplating onto the metallic foam body substrate (a) obtained in step (ii1).

28. Use of the metallic foam body of claim 16 in a physical adsorption or absorption process or in a chemical process.

29. Use according to claim 28, wherein the metallic foam body of claim 1 is used as a precursor for a catalyst or as a catalyst in a process for the production of formaldehyde by oxidation of methanol.

30. Use according to claim 29, wherein the metallic foam body contains at least 99.999 atom % silver and not more than 0.001 atom % of the elements Al, Bi, Cu, Fe, Pb, and Zn.
